(19) United States
(12) Patent Application Publication
(10) Pub. No.: US 2016/0079407 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventors: Nobuyuki AOYAMA, Toshima Tokyo (JP); Ryota YOSHIOKA, Komatsu Ishikawa (JP)

(21) Appl. No.: 14/636,705

(22) Filed: Mar. 3, 2015

(30) Foreign Application Priority Data
Sep. 16, 2014 (JP) 2014-187950

(51) Int. Cl. H01L 29/778; H01L 29/205; H01L 29/49; H01L 29/51; H01L 29/66; H01L 21/28; H01L 21/3213; H01L 21/311; H01L 29/40; H01L 29/20; H01L 29/423

(52) U.S. Cl. CPC H01L 29/7787; H01L 29/2003; H01L 29/205; H01L 29/4966; H01L 29/518; H01L 29/42372; H01L 21/28088; H01L 21/32133; H01L 21/31111; H01L 29/404; H01L 29/66462

(57) ABSTRACT

A semiconductor device includes a first semiconductor layer, a first insulation layer, and a first electrode. The first electrode includes a titanium layer and a titanium nitride layer. The first insulation layer is provided on the first semiconductor layer. The first insulation layer contains silicon nitride. The titanium nitride layer is provided on the first insulation layer. The titanium layer is provided on at least a portion of the titanium nitride layer.

### CROSS-REFERENCE TO RELATED APPLICATION

This application is based upon and claims the benefit of priority from Japanese Patent Application No. 2014-187950, filed Sep. 16, 2014, the entire contents of which are incorporated herein by reference.

### FIELD

Embodiments described herein relate generally to a semiconductor device.

### BACKGROUND

There is a semiconductor device using a nitride semiconductor such as gallium nitride (GaN) or aluminum nitride gallium (AlGaN). In the process of manufacturing the semiconductor device, an annealing process is performed in order to cause ohmic contact between an AlGaN layer and a source electrode and between an AlGaN layer and a drain electrode. As an unintended result of the annealing process, the gate electrode may be peeled off, or partially separated from, the gate insulation layer. As a result, the gate electrode will have a high resistance. In such a semiconductor device, it is desirable to suppress the peeling of the gate electrode.

### DESCRIPTION OF THE DRAWINGS

FIG. 1 is a cross-sectional view schematically illustrating a semiconductor device according to a first embodiment.

FIG. 2 is a cross-sectional view schematically illustrating a portion of the semiconductor device according to the first embodiment.

FIG. 3 is a graph illustrating a film stress property of a gate electrode according to a reference example.

FIG. 4 is a cross-sectional view schematically illustrating a portion of a semiconductor device according to a second embodiment.

FIGS. 5A and 5B are tables presenting experiment results of a semiconductor device according to an embodiment.

FIG. 6 is a graph illustrating a deflection property of a gate electrode according to an embodiment.

FIGS. 7A to 7D are cross-sectional views schematically illustrating a method of manufacturing a semiconductor device according to an embodiment.

### DETAILED DESCRIPTION

Exemplary embodiments provide a semiconductor device that may suppress the gate electrode from being peeled off and thus having high resistance.

In general, according to one embodiment, a semiconductor device includes: a first semiconductor layer, a first, and a first insulation layer electrode. The first electrode includes a titanium layer and a titanium nitride layer. The first insulation layer is provided on the first semiconductor layer. The first insulation layer contains silicon nitride. The titanium nitride layer is provided on the first insulation layer. The titanium layer is provided on at least a portion of the titanium nitride layer.

Hereinafter, each embodiment will be described with reference to the accompanying drawings.

Each drawing is schematic or conceptual. Thus, the relationship between the thickness and the width of each part or element and the size ratio between each element are not necessarily the same as in an actual device. In addition, dimensions of, or a ratio between, parts may be represented differently in different drawings even if the parts are the same.

In the present disclosure, the same parts or elements shown in a drawing as those described previously in the drawings are given the same reference numeral and symbols, and detailed descriptions thereof are appropriately omitted.

### First Embodiment

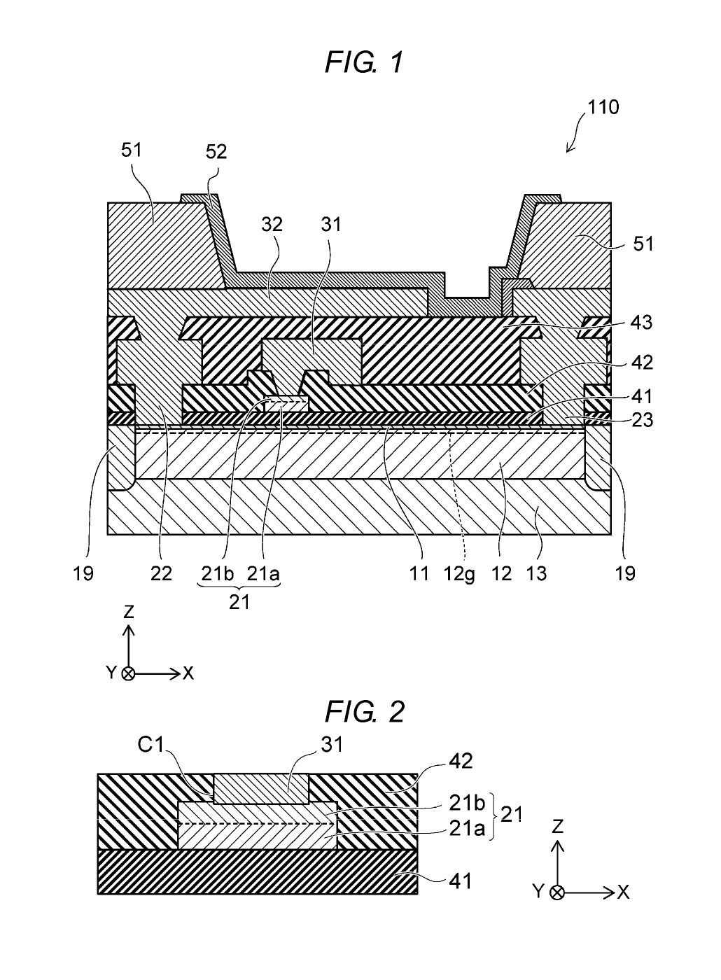

FIG. 1 is a cross-sectional view schematically illustrating a semiconductor device 110 according to the first embodiment.

The semiconductor device 110 is a high electron mobility transistor (HEMT) formed using, for example, a nitride semiconductor.

As illustrated in FIG. 1, the semiconductor device 110 includes a first semiconductor layer 11, a gate electrode 21 (first electrode), a first insulation layer 41, a second semiconductor layer 12, a third semiconductor layer 13, a source electrode 22 (second electrode), and a drain electrode 23 (third electrode). The third semiconductor layer 13 is a ground layer. The second semiconductor layer 12 is provided on the third semiconductor layer 13. The first semiconductor layer 11 is provided on the second semiconductor layer 12. The first insulation layer 41 is provided on the first semiconductor layer 11. Insulation (isolation) areas 19 that electrically separate elements are provided on the first to third semiconductor layers 11 to 13. The source electrode 22, the gate electrode 21, and the drain electrode 23 are provided between the plurality of insulation areas 19.

As materials of the source electrode 22 and the drain electrode 23, aluminum (Al), titanium (Ti), nickel (Ni), gold (Au), tungsten (W), molybdenum (Mo), tantalum (Ta) and the like may be used.

As a material of the third semiconductor layer 13, highly electrically resistant or semi-insulating gallium nitride (GaN) is used.

As a material of the second semiconductor layer 12, Alₓ₁Ga₁₋ₓ₁N (0≦x1<1) is used. The second semiconductor layer 12 is a channel layer.

The first semiconductor layer 11 is different from the second semiconductor layer 12 in composition. As a material of the first semiconductor layer 11, Alₓ₂Ga₁₋ₓ₂N (x1<x2<1) is used, i.e., the aluminum content of the first semiconductor layer 11 is greater than the aluminum content of the second semiconductor layer 12. The first semiconductor layer 11 is a barrier layer.

The first semiconductor layer 11 and the second semiconductor layer 12 form a heterojunction. The thickness of the first semiconductor layer 11 is, for example, in the range of 20 nanometers (nm) or more to 40 nm or less, is 30 nm in this example.

Two-dimensional electron gas 12g is formed near an interface of the second semiconductor layer 12 and the first semiconductor layer 11. An Al composition ratio of the first semiconductor layer 11 is higher than an Al composition ratio of the second semiconductor layer 12. Therefore, the lattice constant of the second semiconductor layer 12 is different from the lattice constant of the first semiconductor layer 11. Accordingly, stress is generated at the interface between the first semiconductor layer 11 and second semiconductor layer 12 so that the two-dimensional electron gas 12g is formed by the piezoelectric effect.

As the material of the first insulation layer 41, silicon nitride (SiN) is used. The first insulation layer 41 functions, for example, as a gate insulation layer.

Here, a direction in a direction from the first semiconductor layer 11 to the gate electrode 21 is referred to as a first direction. The first direction is referred to as the Z axis direction. A direction which is perpendicular to the Z axis direction is referred to as the X axis direction. A direction which is perpendicular to the Z axis direction and the X axis direction is referred to as the Y axis direction. The source electrode 22 and the drain electrode 23 are disposed side by side with the gate electrode 21 along a second direction (X axis direction) intersecting to the first direction. The source electrode 22 is electrically connected to the first semiconductor layer 11. The drain electrode 23 is electrically connected to the first semiconductor layer 11.

“A state of being provided on something” includes a state of being provided with another component interposed therebetween in addition to a state of being provided directly on something. “A state of being electrically connected to something” includes a state in which current flows with another component interposed therebetween, in addition to a state of coming into direct contact with something.

FIG. 2 is a cross-sectional view schematically illustrating a portion of the semiconductor device according to the first embodiment.

As illustrated in FIG. 2, the gate electrode 21 includes a titanium nitride (TiN) layer 21a and a titanium (Ti) layer 21b. The TiN layer 21a is provided on the first insulation layer 41. The Ti layer 21b is provided on the TiN layer 21a. A first field plate FP electrode (first FP electrode) 31, as a conductive portion, is separated from the first insulation layer 41 in the Z axis direction, and is electrically connected to the gate electrode 21. According to the embodiment, the Ti layer 21b is provided between the TiN layer 21a and the first FP electrode 31. That is, the Ti layer 21b is formed over the entire front surface of the TiN layer 21a.

The concentration of the two-dimensional electron gas 12g under the gate electrode 21 is increased or decreased by controlling the voltage applied to the gate electrode 21. Accordingly, the current flowing between the source electrode 22 and the drain electrode 23 is controlled. In the embodiment, a normally-on type or a normally-off type may be used.

For example, the gate electrode 21 is formed in the sequence of the TiN layer 21a and the Ti layer 21b on the first insulation layer 41 (SiN layer) by using a sputtering method without additional heating of the wafer or substrate during the sputter deposition step. The thickness of the TiN layer 21a is, for example, 50 nanometers (nm), and the thickness of the Ti layer 21b is, for example, 10 nm.

The nitrogen content of the TiN layer 21a is, for example, preferably in the range of 40 atomic percent (at %) or more to 60 at % or less. When SiN is used in the first insulation layer 41 it is considered that, if the nitrogen content of the TiN layer 21a is great, the adherence of the TiN layer 21a and the first insulation layer 41 increases. In addition, in view of the adhesion between the TiN layer 21a and the Ti layer 21b, it is preferable that nitrogen content be reduced. Accordingly, the range of 40 at % or more to 60 at % or less of N in the TiN layer 21a is preferable. It is preferable that the nitrogen content of the TiN layer 21a be reduced in the direction from the first insulation layer 41 to the Ti layer 21b, i.e., the N content in the TiN layer at the TiN layer 21a-Ti layer 21b be lower than the H content of the TiN layer 21a at the SiN layer/first insulation layer 41. The adjustment of the nitrogen content included in the TiN layer 21a may be performed, for example, by reducing the nitrogen gas flow rate during the sputter deposition of the TiN layer and thereby “grading” the nitrogen concentration in the depth direction of the TiN layer 21a.

The gate electrode 21 may be formed into a desired pattern, for example, by employing a patterned mask layer on the TiN/Ti layers from which the gate electrode 21 is formed and etching, through the openings in the patterned mask, using a reactive ion etching (RIE) method to remove the Ti/TiN material other than at the gate electrode 21 location(s). Also, a second insulation layer 42 is formed on the gate electrode 21.

A contact hole c1 is formed in the second insulation layer 42, for example, by using the RIE method. The contact hole c1 is an opening in which the contact between the gate electrode 21 and the first FP electrode 31 is formed. The contact hole c1 penetrates the second insulation layer 42, and reaches the front surface of the Ti layer 21b. According to the embodiment, a portion of the front surface of the Ti layer 21b is thus exposed during the etching of the contact hole c1. The first FP electrode 31 is formed on, and extends from, the exposed portion of the front surface of the Ti layer 21b. Accordingly, the gate electrode 21 and the first FP electrode 31 are electrically connected.

The following is a reference example in which the gate electrode is formed only with TiN layer.

In a process of manufacturing a semiconductor device by using a nitride semiconductor, an annealing process is performed between the AlGaN layer and the source electrode, and between the AlGaN layer and the drain electrode, in order to form an ohmic contact therebetween. The annealing process is, for example, performed in a nitrogen atmosphere at a temperature of about 500° C. to 550° C., for 60 seconds. After the annealing process, the interface of the gate electrode between the TiN layer of the gate electrode and the SiN layer of the gate insulation layer may be peeled or blister, i.e., the interfacial contact may fail or partially fail.

It is considered that the peeling of the gate electrode is caused by the film stress of the gate electrode. The factor of the generation of the film stress is roughly divided into (1) a thermal stress due to the difference between the coefficient of thermal expansion of the gate electrode and the coefficient of thermal expansion of the gate insulation layer and (2) an internal stress caused by other factors. Among these, (1) is caused by the difference of materials and the history of heat received by the material. (2) depends on the gate electrode formation condition (electric power, gas flow rate, and heating temperature in sputtering method or the like). The film stress of the gate electrode becomes apparent after the influence of the temperature change (heating and then cooling, with consequent thermal expansion and contraction of the gate electrode materials, the first insulating layer 41 and the underlying semiconductor layers 11, 12) after the annealing process. Deflection occurs in the gate electrode (and substrate or wafer) as a result of the film stress. At this point, if the film stress exceeds the adhesion strength between the gate electrode and gate insulation layer, the gate electrode may be peeled fully or partially off of the gate insulation layer. The film stress mentioned herein is expressed, for example, by the deflection amount. That is, as the film stress increases, the deflection amount increases.

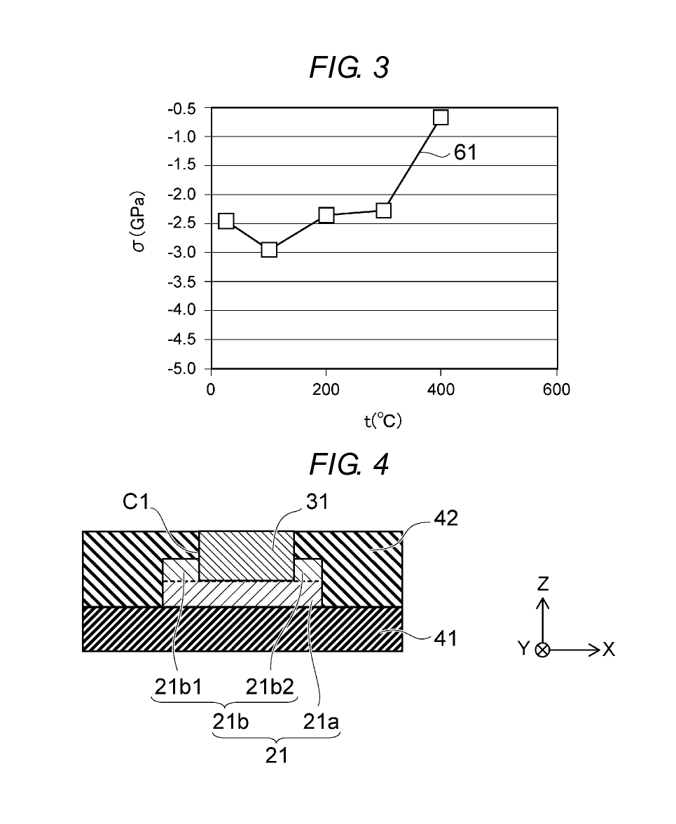

FIG. 3 is a graph illustrating a film stress property of a gate electrode according to a reference example.

In FIG. 3, σ in a vertical axis expresses a film stress of the gate electrode (gigapascal: GPa), and t in a horizontal axis expresses a formation temperature (° C.) of the gate electrode. The sign “−” of the film stress σ indicates a direction with respect to an unstressed “0” reference (tensile direction or compression direction). The gate electrode is configured as a TiN single layer with a thickness of 50 nm. The gate electrode is formed using the sputtering method. The gate insulation layer on which the TiN gate electrode is formed is formed of SiN with a thickness of 10 nm. A film stress property 61 expresses the relationship between the formation temperature t of the gate electrode and the film stress σ of the gate electrode after the annealing treatment (nitrogen atmosphere, about 500° C., 60 seconds) is performed. Also, in the relationship determined definitively by the film thickness of the gate electrode, the thickness, the diameter, and the Poisson's ratio of the wafer, the film stress σ of the gate electrode is obtained by measuring a deflection amount or a curvature of a wafer, and the film stress is greater as the deflection amount of a film with the same film thickness is greater.

In order to suppress the peeling of the gate electrode, the deflection amount derived from the film stress of the TiN of the gate electrode must be decreased. Referring to the film stress property 61, it is understood that the film stress σ is decreased by increasing the formation temperature t to about 400° C. That is, when the gate electrode is formed by using the sputtering method, the film is heated to about 400° C. or more. Accordingly, the film stress σ of the gate electrode is decreased, and the deflection amount after the structure is cooled is decreased. This decrease is a result of a decrease in the internal stress described in (2) above, which is decreased as a result of depositing the TiN layer of the gate electrode at an elevated wafer (structure) temperature of 400° C. or more.

However, in the method of depositing the TiN layer heating as described above, there is possibility that the peeling of the TiN layer from the underlying insulating layer on the wafer during heating or cooling may occur. A mechanism for heating or cooling the wafer (electrostatic chuck, cooling chamber, intermediate heating chamber, or the like) and a space for installing the heating and cooling mechanisms, are also required. Since the number of steps needed to properly heat and cool the wafer increases the number of steps, and the equipment required, to deposit the TiN layer, the cost to process the wafer, and the time period needed to complete the semiconductor device on the wafer, is increased. Electric power for heating is also required, increasing the cost of manufacturing the semiconductor device.

According to the embodiment, the TiN layer and the Ti layer are sequentially formed as the gate electrode on the gate insulation layer (SiN layer), and the gate electrode is then annealed. After the annealing treatment, the atoms therein are rearranged, and the film stress that a stacked film of the Ti layer, the TiN layer, and the SiN layer imposes on the wafer decreases. Specifically, it is found that film stress is greatly decreased by annealing the stacked structure of the TiN layer and the Ti layer. In contrast, in a combination of the Ti single layer and the SiN layer, or the combination of the TiN single layer and the SiN layer, a decrease of the stress by annealing does not occur.

It is well known that the film stress in a single layer of Titanium is tensile, and the film stress in a single TiN layer is compressive. However, in a comparison between the absolute value of the tensile stress of a single Ti layer and the absolute value of the compressive stress of a single TiN layer, the absolute value of the compressive stress of the single TiN layer tends to be remarkably higher. It is believed that in the Ti/TiN layer stack, the compressive and tensile stresses offset each other by the combination of the Ti layer and the TiN layer. It is considered that the film stress in the stacked Ti/TiN layer may be decreased by combining a Ti layer under tensile stress when deposited with a thin TiN layer with a comparatively higher compressive stress value.

In the stacked structure according to the embodiment, it is possible to prevent the peeling of the gate electrode at the interface between the gate electrode and the gate insulation layer. It is possible to suppress the gate electrode from having high resistance by suppressing the gate electrode from being peeled off.

Also, since the stacked structure of the gate electrode is formed (deposited) by using the sputtering method without separate heating of the wafer during deposition of the Ti and TiN layers, cracks in the wafer caused during the heating or cooling thereof are suppressed. Dedicated equipment for heating and cooling the wafer are not required, and manufacturing cost is decreased. Individual steps for heating and cooling of the wafer are not required, and productivity is thus enhanced. Electric power for heating is not required, and the electric power may be saved.

As the material of the gate electrode in the prior art, Ni, Au, and the like are generally used in the art, and the gate electrode is formed by the evaporation method.

On the contrary, in the embodiment herein, instead of Ni or Au, TiN is used. For example, TiN is formed by the sputtering method. The sputtering method has higher productivity and is more advantageous than the evaporation method. It is possible to form a film with a material other than pure metal by using the sputtering method. Accordingly, the embodiment is more advantageous in view of the productivity, in addition to the suppression of the peeling of the gate electrode.

Also, in the example, the first FP electrode 31 is provided. The first FP electrode 31 is provided on the gate electrode 21, and is electrically connected to the gate electrode 21. The first FP electrode 31 includes a portion that comes into contact with the gate electrode 21, and a portion provided on the second insulation layer 42 between the gate electrode 21 and the drain electrode 23. The first FP electrode 31 is a portion of gate wiring that supplies gate bias to the gate electrode 21, and at the same time, functions as a field plate.

A portion of the second insulation layer 42 extends between the first FP electrode 31 and the first insulation layer 41. The second insulation layer 42 covers a portion of the front surface of the gate electrode 21. Further, the second insulation layer 42 covers a side surface of the gate electrode 21 (a surface intersecting the X axis direction or extending in the Y axis direction). Further, a third insulation layer 43 covers the second insulation layer 42 and the first FP electrode 31. The second insulation layer 42 and the third insulation layer 43 function as an interlayer insulation layer (interlayer insulation film).

As the material of the interlayer insulation layer, for example, silicon oxide (SiO₂) or silicon nitride (SiN) may be used. As the material of the second insulation layer 42, for example, SiN is used. As the material of the third insulation layer 43, for example, SiO₂ is used.

In this example, a second field plate electrode (hereinafter referred to as a second FP electrode) 32 is provided. The second FP electrode 32 is spaced from the gate electrode 21 and the first FP electrode 31 in the Z axis direction. A portion of the second FP electrode 32 extends over the gate electrode 21 and the first FP electrode 31 with the third insulation layer 43 provided therebetween, and terminates at a position between the gate and drain electrodes. The second FP electrode 32 is electrically connected to the source electrode 22. The second FP electrode 32 includes a portion positioned between the first FP electrode 31 and the drain electrode 23 in the X axis direction.

As the material of the first FP electrode 31 and the second FP electrode 32, for example, aluminum (Al) and titanium (Ti) may be used.

The first FP electrode 31 and the second FP electrode 32 alleviate the electric field concentration created, for example, at the edge on the drain electrode 23 side of the gate electrode 21. The breakdown voltage increases by providing the FP electrode so that the reliability of the device is enhanced.

Further, in the example, a pad portion 51 and a protection film 52 are provided on the second FP electrode 32 and the third insulation layer 43. As the material of the pad portion 51, for example, Ti and Al may be used. As the material of the protection film 52, for example, SiN may be used.

### Second Embodiment

FIG. 4 is a cross-sectional view schematically illustrating a portion of a semiconductor device according to a second embodiment.

As illustrated in FIG. 4, the Ti layer 21b includes a first part 21b1 and a second part 21b2. The second part 21b2 is spaced from the first part 21b1 in the X axis direction. The first FP electrode 31 is provided between the first part 21b1 and the second part 21b2. The first part 21b1, the second part 21b2, and the first FP electrode 31 are electrically connected to the TiN layer 21a. For example, the first part 21b1, the second part 21b2, and the first FP electrode 31 are connected to the TiN layer 21a. That is, according to the embodiment, the Ti layer 21b is formed on only a portion of the front surface of the TiN layer 21a.

The gate electrode 21 is formed in the sequence of the TiN layer 21a and the Ti layer 21b on the first insulation layer 41 by using the sputtering method without heating the wafer. The thickness of the TiN layer 21a is, for example, 50 nm, and the thickness of the Ti layer 21b is, for example, 10 nm.

The gate electrode 21 is, for example, formed into a desired pattern by using a patterning method to provide a patterned mask and etching using the RIE method. Also, the second insulation layer 42 is formed on the gate electrode 21.

The contact hole c1 is formed on the second insulation layer 42, for example, through a patterned mask thereover using the RIE method. The contact hole c1 is a hole for contact between the gate electrode 21 and the first FP electrode 31. The contact hole c1 penetrates the second insulation layer 42 and the Ti layer 21b, and reaches the front surface of the TiN layer 21a. In the embodiment, a portion of the front surface of the TiN layer 21a is exposed. Also, the first FP electrode 31 is formed on the portion of the front surface of the TiN layer 21a exposed during etching of the contact hole c1. Accordingly, the gate electrode 21 and the first FP electrode 31 are electrically connected.

According to the embodiment, the TiN layer is formed on the gate insulation layer (SiN layer) as the gate electrode, and the Ti layer is provided on a portion of the TiN layer so that the gate electrode is formed to be the stacked structure of TiN and Ti. Accordingly, the peeling of the gate electrode between the gate electrode and the gate insulation layer is suppressed.

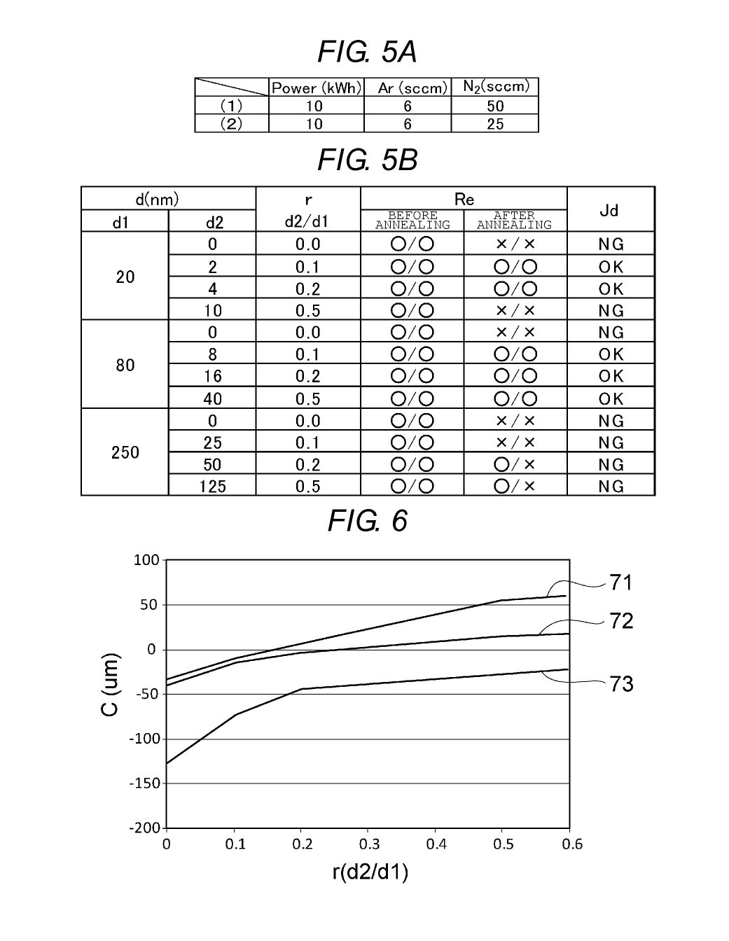

FIGS. 5A and 5B are tables presenting experiment results of the semiconductor device according to an embodiment.

FIG. 5A presents conditions for forming the gate electrode 21.

FIG. 5B presents experiment results of the peeling of the gate electrode 21.

The gate electrode 21 has the stacked structure of FIG. 2. The gate electrode 21 is obtained by stacking the Ti layer 21b over the entire surface of the TiN layer 21a. The gate electrode 21 is formed by using the sputtering method without heating. The gate insulation layer is formed of a SiN layer with the thickness of 10 nm.

As illustrated in FIG. 5A, Condition 1 is a first formation condition of the gate electrode 21. In the case of Condition 1, the high frequency power (Power) is 10 kilowatt hour (kWh). The argon flow rate (Ar) is 6 sccm (Standard cc/min). Also, the unit “sccm” is a unit of volume flow rate defined in the standard condition (1 atmospheric pressure, 0° C.). The nitrogen flow rate (N₂) is 50 sccm. Condition 2 is a second formation condition of the gate electrode 21. In the case of Condition 2, the high frequency power (Power) is 10 kWh. The argon flow rate (Ar) is 6 sccm. The nitrogen flow rate (N₂) is 25 sccm.

As illustrated in FIG. 5B, a thickness d is the thickness of the gate electrode 21. A thickness d1 is the thickness of the TiN layer 21a. A thickness d2 is the thickness of the Ti layer 21b. That is, d=d1+d2 is satisfied. The unit thereof is a nanometer (nm). A thickness ratio r presents the ratio between the thickness d1 of the TiN layer 21a and the thickness d2 of the Ti layer 21b (d2/d1). Results represent whether the gate electrode 21 is peeled off respectively in Condition 1 and Condition 2 before annealing, and whether the gate electrode 21 is peeled off respectively in Condition 1 and Condition 2 after annealing. In addition, the annealing condition is about 550° C. for 60 seconds in a nitrogen atmosphere. “O” means that peeling does not exist, and “X” means that peeling exists. “O/O” means that peeling does not exist in both of Conditions 1 and 2. “X/X” means that peeling exists in both of Conditions 1 and 2. “O/X” means that peeling does not exist in Condition 1, and peeling exists in Condition 2. The determinations Jd show “NG” indicating failure when even one “X” is included in the results Re, and show “OK” indicating success when all are “O”.

For example, with respect to the TiN layer 21a with the thickness of 20 nm, the thicknesses of the Ti layer 21b of 0, 2, 4, and 10 nm are combined. At this point, the thickness ratios r become 0, 0.1, 0.2, and 0.5, in sequence. With respect to the thickness ratios r, whether the gate electrode 21 is peeled off or not is visually determined respectively before and after annealing. In this example, when the thickness ratios r are 0.1 and 0.2, the determinations are “OK”.

In the same manner, with respect to the TiN layer 21a with the thickness of 80 nm, the thicknesses of the Ti layer 21b of 0, 8, 16, and 40 nm are combined. The thickness ratios r become 0, 0.1, 0.2, and 0.5, in sequence. With respect to the thickness ratios r, whether the gate electrode 21 is peeled off is visually determined respectively before and after annealing. In this example, when the thickness ratios r are 0.1, 0.2, and 0.5, the determinations are “OK”.

In the same manner, with respect to the TiN layer 21a with the thickness of 250 nm, the thicknesses of the Ti layer 21b of 0, 25, 50, and 125 nm are combined. The thickness ratios r become 0, 0.1, 0.2, and 0.5, in sequence. With respect to the thickness ratios r, whether the gate electrode 21 is peeled off is visually determined respectively before and after annealing. In this example, the determinations are “NG” with respect to all the thickness ratios r.

Based on the results, it is preferable that the thickness d1 of the TiN layer 21a be in the range of 20 nm or more to 80 nm or less. It is preferable that the thickness d2 of the Ti layer 21b be in the range of 10 percent (%) or more to 20% or less of the thickness d1 of the TiN layer 21a. Accordingly, more effectively, the peeling of the gate electrode between the gate electrode and the gate insulation layer is suppressed.

FIG. 6 is a graph illustrating the deflection properties of the gate electrode according to the embodiment.

In FIG. 6, c in the vertical axis labeled C (μm) represents the deflection amount (micrometer: μm) of the gate electrode 21, and r in the horizontal axis labeled r(d1/d2) represents the thickness ratio (d2/d1) between the thickness d1 of the TiN layer 21a and the thickness d2 of the Ti layer 21b. The signs “+” and “−” in the deflection amount c represent the deflection direction (upwardly convex direction or downwardly convex direction) with respect to a flat surface standard. In the example, the results obtained by measuring the deflection amount of the gate electrode 21 after the annealing treatment (nitrogen atmosphere, 550° C., 60 seconds) are presented. The gate electrode 21 is the stacked structure of FIG. 2.

The deflection curve 71 shows the relationship between the thickness ratio r and the deflection amount c when the thickness d1 of the TiN layer 21a is 20 nm. The deflection curve 72 shows the relationship between the thickness ratio r and the deflection amount c when the thickness d1 of the TiN layer 21a is 80 nm. The deflection curve 73 shows the relationship between the thickness ratio r and the deflection amount c when the thickness d1 of the TiN layer 21a is 250 nm.

When the thickness d1 is 20 nm (the deflection property 71), if the thickness ratio r is in the range of 0.1 to 0.2, the deflection amount c is small and peeling rarely occurs at the gate electrode 21/gate insulator 41 interface. In the same manner, when the thickness d1 is 80 nm (the deflection property 72), if the thickness ratio r is in the range of 0.1 to 0.2, the deflection amount c is small, and peeling rarely occurs in the gate electrode 21/gate insulator 41 interface. When the thickness d1 is 250 nm (the deflection property 73), the deflection amount c is comparatively large regardless of the thickness ratio r.

According to the results of FIGS. 5 and 6, one may see that whether the gate electrode 21 will be peeled off or not relates to the deflection amount. That is, if the deflection amount is small, the gate electrode 21 is nearly never peeled off. Accordingly, it is also preferable that the thickness d1 of the TiN layer 21a be in the range of 20 nm or more to 80 nm or less. It is also preferable that the thickness d2 of the Ti layer 21b be in the range of 10% or more to 20% or less of the thickness d1 of the TiN layer 21a.

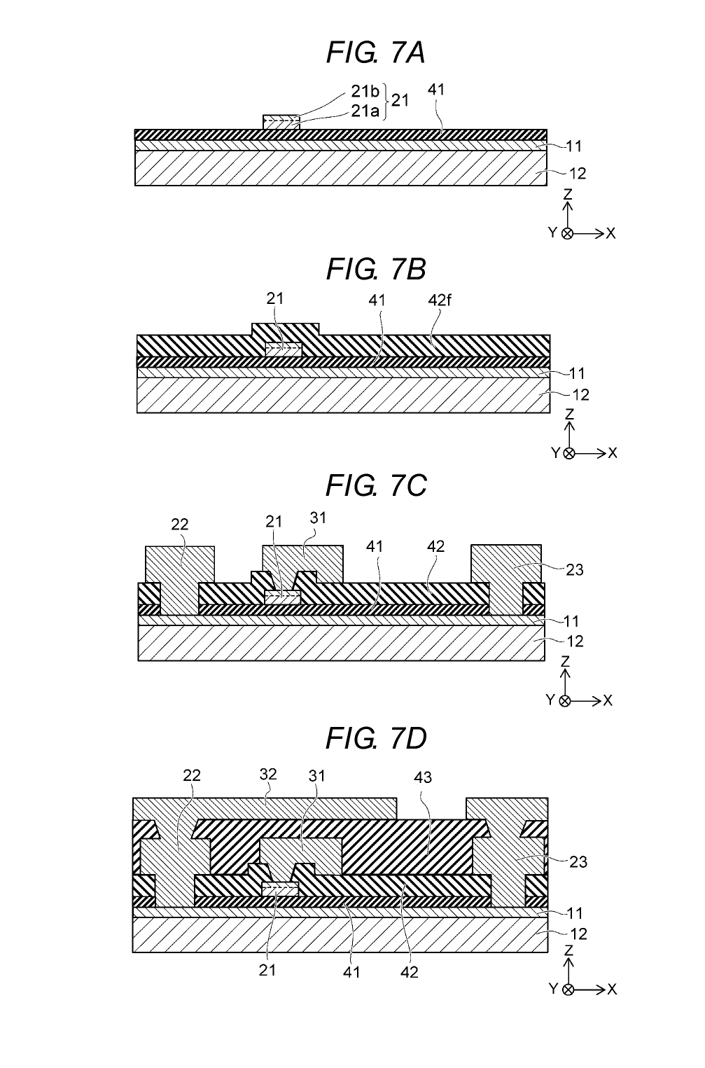

FIGS. 7A to 7D are cross-sectional views schematically illustrating a method of manufacturing the semiconductor device 110 according to the embodiment.

As illustrated in FIG. 7A, the first insulation layer (gate insulation layer) 41 is formed on the wafer on which the second semiconductor layer 12 and the first semiconductor layer 11 are formed.

The SiN film to be used as the first insulation layer 41 is formed, for example, by a low pressure chemical vapor deposition (LP-CVD) method. The thickness of the first insulation layer 41 is, for example, in the range of 10 nm or more to 30 nm or less, and is 20 nm in this example.

The TiN layer 21a and the Ti layer 21b to be the gate electrode 21 are sequentially formed on the first insulation layer 41. The TiN film and the Ti film are processed by using lithography and etching, and the gate electrode 21 is formed. The TiN film and the Ti film are formed, for example, by the sputtering method without heating. In the etching step, for example, the RIE method may be used.

The width of the gate electrode 21 (length in X axis direction) is, for example, in the range of 1.0 micrometer (μm) or more to 3.0 μm or less. In the example, the width is 2.0 μm.

As illustrated in FIG. 7B, a SiN film 42f to be the second insulation layer 42 is formed. The SiN film 42f is provided to cover the gate electrode 21 and the first insulation layer 41. To form the SiN film 42f, the plasma CVD method may be used for example. In the formation of the SiN film 42f using the plasma CVD method, for example, SiH₄ gas, NH₃ gas, and N₂ gas are used.

As illustrated in FIG. 7C, openings are provided in the SiN film 42f according to the positions in which the source electrode 22 and the drain electrode 23 are to be provided, and a metal film (for example, a Ti film or an Al film) is formed by the sputtering method to fill these openings. The source electrode 22 and the drain electrode 23 are formed by processing the metal film by forming a patterned etch mask by lithography followed by etching through the SiN film 42f to form openings for the source and drain electrodes (22, 23) to contact the semiconductor layer 11, and to open the SiN film 42f over the gate electrode. In the same manner, the first FP electrode 31 is formed in the opening over the gate electrode 21.

The width of the source electrode 22 is, for example, in the range of 3 μm or more to 8 μm or less. In the example, the width is 5 μm.

The width of the drain electrode 23 is, for example, in the range of 3 μm or more to 8 μm or less. In the example, the width is 5 μm.

The distance between the adjacent side of the source electrode 22 and the gate electrode 21 is, for example, in the range of 1 μm or more to 3 μm or less. In the example, the distance is 2 μm.

The distance between the gate electrode 21 and the drain electrode 23 is, for example, in the range of 5 μm or more to 20 μm or less. In the example, the distance is 14 μm.

As illustrated in FIG. 7D, a SiO₂ film to form the third insulation layer 43 is deposited. The SiO₂ film covers the first FP electrode 31, the source electrode 22, the drain electrode 23, and the second insulation layer 42. Also, the second FP electrode 32 is further formed over the SiO₂ film.

Further, the pad portion, the protection film, and the like are then formed to complete the semiconductor device 110.

Also, the first to third semiconductor layers 11 to 13 are not limited to a nitride semiconductor. For example, another semiconductor such as SiC, GaAs, InP, and SiGe may be used.

In the specification, the nitride semiconductor includes all kinds of semiconductors in which composition ratios x, y, and z are changed in the respective rages of the chemical formula BₓIn_{y}Al_{z}G_{a1-x-y-z}N (0≦x≦1, 0≦y≦1, 0≦z≦1, and x+y+z≦1). In the chemical formula, it is assumed that one including the group V element other than N (nitrogen), one further including various kinds of elements added for controlling various kinds of physical properties such as conductivity, and one including various kinds of elements unintentionally included are also included in the nitride semiconductor.

According to the embodiment, it is possible to provide a semiconductor device that may suppress the gate electrode from being peeled off, and having high resistance.

In the above, while referring to specific examples, embodiments of the invention are described. However, the disclosure is not limited to the specific examples. For example, specific configurations of the first semiconductor layer, the first insulation layer, the first electrode, and the like are included in the scope of the invention, as long as the invention may be performed in the same manner by appropriately selecting the specific configurations in the well-known scope by a person having ordinary skilled in the art to achieve the same advantage.

Also, combinations of two or more elements of respective specific examples in the technically available scope are included in the scope of the invention as long as the combinations include the gist of the invention.

In addition, all semiconductor devices that may be practiced by appropriately changing designs by a person having ordinary skilled in the art based on the semiconductor device described above as embodiment of the invention are included in the scope of the invention, as long as the semiconductor devices include the gist of the invention.

In addition, in a category of the spirit of the embodiments, those skilled in the art can derive various modified examples and corrected examples, and the modified examples and the corrected examples are understood to be also included in the range of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer;
a first insulation layer on the first semiconductor layer, and comprising silicon nitride; and
a first electrode comprising a titanium nitride layer on the first insulation layer, and a titanium layer on at least a portion of the titanium nitride layer.

2. The device according to claim 1, further comprising:
a conductive portion electrically connected to, and extending from, the first electrode,
wherein the titanium layer is located between the titanium nitride layer and the conductive portion.

3. The device according to claim 1, further comprising:
a conductive portion electrically connected to, and extending from, the first electrode,
wherein the titanium layer includes a first part and a second part located on the titanium nitride layer and spaced from one another, and
wherein the conductive portion is provided between the first part and the second part.

4. The device according to claim 1,
wherein a thickness of the titanium nitride layer is in a range from 20 nanometers or more to 80 nanometers or less, and
wherein a thickness of the titanium layer is in a range from 10 percent or more to 20 percent or less of the thickness of the titanium nitride layer.

5. The device according to claim 1,
wherein the nitrogen content of the titanium nitride layer is in a range of 40 atomic percent or more to 60 atomic percent or less.

6. The device according to claim 1, further comprising:
a second semiconductor layer,
wherein the first semiconductor layer is provided between the first insulation layer and the second semiconductor layer,
wherein the second semiconductor layer contains Alₓ₁Ga₁₋ₓ₁N (0≦x1<1), and
wherein the first semiconductor layer contains Alₓ₂Ga₁₋ₓ₂N (x1<x2<1).

7. The device according to claim 6,
wherein the second semiconductor layer forms a heterojunction with the first semiconductor layer.

8. The device according to claim 7, further comprising:
a second electrode electrically connected to the first semiconductor layer; and
a third electrode electrically connected to the first semiconductor layer,
wherein the first electrode is provided between the second electrode and the third electrode.

9. A method of manufacturing a semiconductor device, comprising:
providing a semiconductor substrate comprising a first semiconductor layer and a second semiconductor layer on the first semiconductor layer;
depositing a first insulating layer over the second semiconductor layer;
depositing a titanium nitride layer on the first insulating layer and reducing the nitrogen content in the titanium nitride layer as it is deposited, and depositing a titanium layer on the titanium nitride layer, without applying an external heating source to the substrate during the deposition of both the titanium nitride and titanium layers;
pattern etching the titanium and titanium nitride layers to form a stacked electrode structure therefrom; and
annealing the titanium nitride and titanium layers.

10. The method of claim 9, wherein the thickness of the titanium layer is at least ten percent, but no more than twenty percent, of the thickness of the titanium nitride layer.

11. The method of claim 9, further comprising depositing a second insulating layer over the first insulating layer and the stacked electrode.

12. The method of claim 11, further comprising pattern etching the second insulating layer to form an opening therethrough and exposing the stacked electrode in the opening; and
depositing a first conductor in the opening in the second insulating layer and contacting the stacked electrode therewith.

13. The method of claim 12, further comprising:
pattern etching the titanium layer exposed in the opening in the second insulating layer to provide an opening therethrough exposing the titanium nitride layer in the opening before depositing the first conductor, wherein
the first conductor contacts surfaces of both the titanium layer and the titanium nitride layer.

14. The method of claim 12, further comprising:
depositing a third insulating layer over the second insulating layer; and
forming a conductive contact on the first semiconductor layer and extending the conductive contact through the first, second and third insulating layers, and over the portion of the third insulating layer overlying the stacked electrode.

15. The method of claim 14, wherein the stacked electrode comprises a gate electrode, and the conductive contact comprises a source electrode and the portion thereof extending over the gate electrode comprises a field plate electrode.

16. A nitride semiconductor device, comprising:
a first nitride semiconductor layer;
a second nitride semiconductor layer having a different nitrogen concentration than the first nitride semiconductor layer located over the first semiconductor layer;
a source electrode in ohmic contact with the second nitride semiconductor layer;
a drain electrode in ohmic contact with the second nitride semiconductor layer;
a gate insulating layer on the second nitride semiconductor layer and located between the source and the drain electrodes; and
a gate electrode comprising titanium nitride disposed on the gate insulating layer and a titanium layer located on the titanium nitride layer on a side thereof opposite to the location of the gate insulating layer, wherein the nitrogen content of the titanium nitride layer is greater adjacent to the gate insulating layer than adjacent to the titanium layer.

17. The nitride semiconductor device of claim 16, further comprising:
a first interlayer insulating layer overlying the gate electrode and the gate insulating layer; and
a first field plate electrode extending through the first interlayer insulating layer and contacting the gate electrode.

18. The nitride semiconductor device of claim 17, wherein the titanium layer overlies only a portion of the titanium nitride layer, and the first field plate electrode extends into contact with a surface of the titanium nitride layer and a surface of the titanium layer.

19. The semiconductor device of claim 17, further comprising:
a second interlayer insulating layer; and
a second field plate electrode extending from the source electrode and over the second interlayer insulating film, and over the gate electrode and first field plate electrode.

20. The semiconductor device of claim 19, wherein the second field plate electrode terminates on the second interlayer insulating layer at a location between the drain electrode and gate electrode.
